(19) United States
(12) Patent Application Publication
(10) Pub. No.: US 2024/0284713 A1
(43) Pub. Date: Aug. 22, 2024

(54) OLED DISPLAY PANEL AND OLED DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Qingsong LIU, Wuhan (CN)

(21) Appl. No.: 18/387,131

(22) Filed: Nov. 6, 2023

(30) Foreign Application Priority Data
Feb. 17, 2023 (CN) 202310140094.1

(51) Int. Cl. H10K 59/122; H10K 59/124; H10K 59/126

(52) U.S. Cl. CPC H10K 59/122; H10K 59/124; H10K 59/126

(57) ABSTRACT

An OLED display panel includes a substrate, a driving circuit layer, a light-emitting functional layer, an encapsulation layer, and a touching layer. The driving circuit layer includes a first inorganic layer having a plurality of inorganic film layers. The touching layer includes a second inorganic layer having one or more inorganic film layers. A sum of a number of the inorganic film layers of the first inorganic layer and the second inorganic layer in a cutting area is less than a sum of a number of the inorganic film layers of the first inorganic layer and the second inorganic layer in a display area.

### CROSS-REFERENCE TO RELATED DISCLOSURE

This disclosure claims priority to and the benefit of Chinese Patent Disclosure No. 202310140094.1, filed on Feb. 17, 2023, the disclosure of which is incorporated herein by reference in its entirety.

### TECHNICAL FIELD

The present disclosure relates to display technologies, and in particular, to an OLED display panel and an OLED display device.

### BACKGROUND

Organic light-emitting diode (OLED) display devices are widely used in various fields because of their lightweight, wide viewing angle, fast response, low temperature resistance, high luminous efficiency, and an ability to manufacture curved flexible display screens. Laser is used to cut display screens in a process of manufacturing the OLED display devices. During the cutting process, cutting edges of OLED display devices easily produce micro-cracks influenced by the laser. These micro-cracks will diffuse to a display area affected by bending, heating, and humidification, as a result, water and oxygen invade into the display area from the cracks, and the display effect is affected.

Therefore, the existing OLED display devices have the technical problem that the micro-cracks generated by the cutting edges diffuse into the display area, resulting in encapsulation failure.

### SUMMARY

In view of the above, an embodiment of the present disclosure provides an OLED display panel and an OLED display device, to alleviate a technical problem that micro-cracks generated by cutting edges of the existing OLED display devices diffuse into the display area, resulting in encapsulation failure.

An embodiment of the present disclosure provides an OLED display panel including a substrate, a driving circuit layer, a light-emitting functional layer, an encapsulation layer, and a touching layer. The driving circuit layer is disposed on the substrate and includes a first inorganic layer having a plurality of inorganic film layers. The light-emitting functional layer is disposed on a side of the driving circuit layer away from the substrate. The encapsulation layer is disposed on a side of the light-emitting functional layer away from the driving circuit layer. The touching layer is disposed on a side of the encapsulation layer away from the light-emitting functional layer and includes a second inorganic layer having one or more inorganic film layers. The OLED display panel further includes a display area and a non-display area, and the non-display area includes a cutting area disposed at a side of the display area. A sum of a number of the inorganic film layers of the first inorganic layer and the second inorganic layer in the cutting area is less than a sum of a number of the inorganic film layers of the first inorganic layer and the second inorganic layer in the display area.

In some embodiments, in the display area, the first inorganic layer includes a buffer layer, a first gate insulating layer, a second gate insulating layer, and an interlayer insulating layer, and the second inorganic layer includes a first touching insulating layer and a second touching insulating layer; in the cutting area, the OLED display panel includes five or fewer film layers among the buffer layer, the first gate insulating layer, the second gate insulating layer, the interlayer insulating layer, the first touching insulating layer, and the second touching insulating layer.

In some embodiments, the encapsulation layer includes a first inorganic encapsulation layer, a second inorganic encapsulation layer, and an organic encapsulation layer disposed between the first inorganic encapsulation layer and the second inorganic encapsulation layer; the OLED display panel further includes a flat layer disposed on a side of the touching layer away from the encapsulation layer; in the cutting area, a side of the light-emitting functional layer is in contact with the substrate, and the other side of the light-emitting functional layer is in contact with the first inorganic encapsulation layer, the first inorganic encapsulation layer is in contact with the second inorganic encapsulation layer, and the second inorganic encapsulation layer is in contact with the flat layer.

In some embodiments, the light-emitting functional layer includes a hole transport layer, a light-emitting layer, an electron transport layer, and a common electrode layer, the light-emitting layer is disposed between the hole transport layer and the electron transport layer, and the electron transport layer is disposed between the light-emitting layer and the common electrode layer; in the cutting area, the hole transport layer is in contact with the substrate, and the common electrode layer is in contact with the first inorganic encapsulation layer.

In some embodiments, the driving circuit layer further includes a first planarization layer and a second planarization layer disposed between the first planarization layer and the light-emitting functional layer; the light-emitting functional layer further includes a pixel defining layer disposed between the second planarization layer and the encapsulation layer; the OLED display panel further includes a spacer column and a retaining wall disposed between the substrate and the light-emitting functional layer in the cutting area, and the retaining wall includes the first planarization layer, the second planarization layer, the pixel definition layer, and the spacer column stacked in sequence.

In some embodiments, the OLED display panel further includes a metal pattern disposed at one or more sides of the light-emitting functional layer in the cutting area.

In some embodiments, the driving circuit layer further includes a first metal layer, a second metal layer, a first source-drain layer, and a second source-drain layer; in the cutting area, the metal pattern is disposed between the light-emitting functional layer and the substrate, and one of the first metal layer, the second metal layer, the first source-drain layer, and the second source-drain layer comprises the metal pattern.

In some embodiments, the metal pattern is disposed between the light-emitting functional layer and the first inorganic encapsulating layer in the cutting area; the OLED display panel further includes a metal layer, and the metal pattern is disposed in the metal layer.

In some embodiments, the light-emitting functional layer further includes a common electrode layer; the non-display area includes an encapsulation area located between the display area and the cutting area, and the metal pattern is in contact with the common electrode layer at a junction of the display area and the encapsulation area.

An embodiment of the present disclosure provides an OLED display device including an OLED display panel mentioned above and an electronic element.

Beneficial effects are as follows: The OLED display panel and the OLED display device are provided by the present disclosure. The OLED display panel includes the substrate, the driving circuit layer, the light-emitting functional layer, the encapsulation layer, and the touching layer. The driving circuit layer is disposed on the side of the substrate and includes the first inorganic layer having the plurality of inorganic film layers. The light-emitting functional layer is disposed on the side of the driving circuit layer away from the substrate. The encapsulation layer is disposed on the side of the light-emitting functional layer away from the driving circuit layer. The touching layer is disposed on the side of the encapsulation layer away from the light-emitting functional layer and includes a second inorganic layer having one or more inorganic film layers. The OLED display panel further includes the display area and the non-display area, and the non-display area includes the cutting area disposed at the side of the display area. The sum of the number of the inorganic film layers of the first inorganic layer and the second inorganic layer in the cutting area is less than the sum of a number of the inorganic film layers of the first inorganic layer and the second inorganic layer in the display area, so that part of the inorganic layers in the cutting area may be removed, and the number of the inorganic layers located in the cutting area is fewer. Since micro-cracks are not easy to diffuse in the organic layers, the number of the film layers in which the micro-cracks may diffuse is reduced, and difficulties of crack diffusion are increased, so that when the OLED display panel generates the micro-cracks, the micro-cracks are not easy to diffuse into the display area, thereby avoiding the problem of encapsulation failure caused by the crack diffusion to the display area.

### BRIEF DESCRIPTION OF THE DRAWINGS

The technical solutions, as well as other beneficial advantages, of the present disclosure will be apparent from the following detailed descriptions of embodiments of the present disclosure, with reference to the attached drawings.

FIG. 1 is a first schematic diagram of an OLED display panel provided by an embodiment of the present disclosure.

FIG. 2 is a second schematic diagram of the OLED display panel provided by an embodiment of the present disclosure.

FIG. 3 is a third schematic diagram of the OLED display panel provided by an embodiment of the present disclosure.

FIG. 4 is a fourth schematic diagram of the OLED display panel provided by an embodiment of the present disclosure.

### DETAILED DESCRIPTION

The technical solutions in embodiments of the present disclosure will be described clearly and completely hereafter with reference to the accompanying drawings. Apparently, described embodiments are only a part of but not all embodiments of the present disclosure. All other embodiments obtained by persons of ordinary skill in the art based on the embodiments of the present disclosure without creative efforts shall fall within a protection scope of the present disclosure.

In the description of this embodiment, terms indicating orientation or location relationships such as “center”, “vertical”, “horizontal”, “length”, “width”, “thickness”, “upper”, “up”, “down”, “rear”, “front”, “left”, “right”, “vertical”, “horizontal”, “top”, “bottom”, “inner”, “outer”, “clockwise”, and “counterclockwise” are based on orientation or location relationships shown in drawings, which are only for a convenience of description and simplified operation, rather than indicating or implying that devices or elements referred to must have a specific orientation, be constructed and operated in a specific orientation, so it cannot be understood as a limitation of the present disclosure. In addition, terms “first” and “second” are used herein for purposes of description, and should not be interpreted as indication or implication of relative importance, or implied indication of a number of the technical features. Therefore, features limited by terms such as “first” and “second” can explicitly or impliedly include one or more than one of these features. In description of the disclosure, “a plurality of” means two or more than two, unless otherwise specified.

In description of the present disclosure, it should be noted that unless otherwise specified and defined, terms “connected” and “fixed” should be understood in a broad sense, for example, it may be a fixed connection, a detachable connection, or a whole; it may be a mechanical connection or an electrical connection; it may be a directly connection or an indirectly connection through an intermediate media; and it may be an internal connection of two components or an interaction relationship between two components. For those skilled in the art, meanings of the above terms in the present disclosure can be understood according to situations.

In the present disclosure, unless otherwise specified and defined, a first feature is disposed “on” or “under” a second feature may include a direct contact between the first feature and the second feature, or a contact between the first feature and the second feature through other features rather than the direct contact. Moreover, that the first feature is disposed “above” or “up” the second feature includes that the first feature is directly above or obliquely above the second feature, or only indicate that a horizontal height of the first feature is greater than a horizontal height of the second feature. That the first feature is disposed “below”, “under”, or “underneath” of the second feature include that the first feature is directly below or obliquely below the second feature, or only indicate that the horizontal height of the first feature is less than the horizontal height of the second feature.

Various embodiments and examples are provided in the following description to implement different structures of the present disclosure. In order to simplify the present disclosure, certain elements and settings will be described. However, these elements and settings are only by way of example and are not intended to limit the present disclosure. In addition, reference numerals may be repeated in different examples in the present disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied.

In view of a technical problem that micro-cracks generated by cutting edges of the existing organic light-emitting diode (OLED) display devices diffuse into the display area, resulting in encapsulation failure, an embodiment of the present disclosure provides an OLED display panel and an OLED display device, to alleviate the aforementioned technical problem.

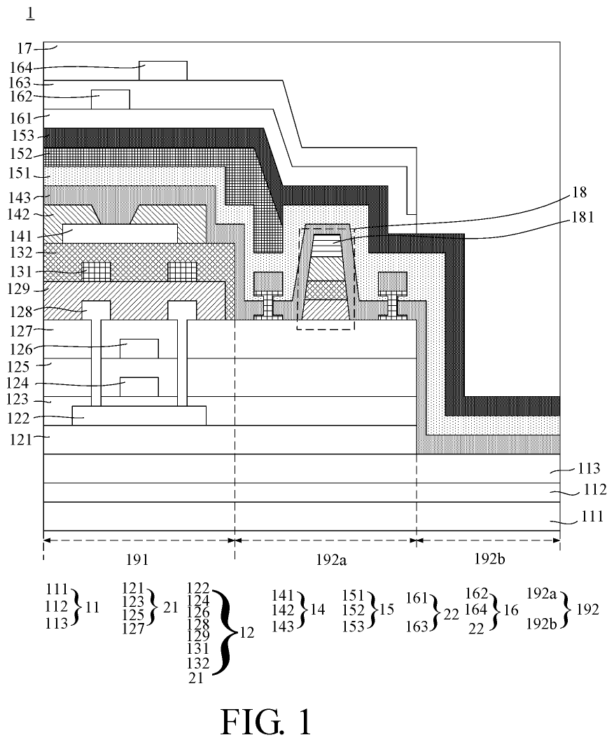

Referring to FIG. 1, an embodiment of the present disclosure provides an OLED display panel 1 including a substrate 11, a driving circuit layer 12, a light-emitting functional layer 14, an encapsulation layer 15, and a touching layer 16. The driving circuit layer 12 is disposed on the substrate 11 and includes a first inorganic layer 21 having a plurality of inorganic film layers. The light-emitting functional layer 14 is disposed on a side of the driving circuit layer 12 away from the substrate 11. The encapsulation layer 15 is disposed on a side of the light-emitting functional layer 14 away from the driving circuit layer 12. The touching layer 16 is disposed on a side of the encapsulation layer 15 away from the light-emitting functional layer 14 and includes a second inorganic layer 22 having one or more inorganic film layers. The OLED display panel 1 further includes a display area 191 and a non-display area 192, and the non-display area 192 includes a cutting area 192b disposed at a side of the display area 191. A sum of a number of the inorganic film layers of the first inorganic layer 21 and the second inorganic layer 22 in the cutting area 192b is less than a sum of a number of the inorganic film layers of the first inorganic layer 21 and the second inorganic layer 22 in the display area 191. For example, the sum of the number of the inorganic film layers of the first inorganic layer 21 and the second inorganic layer 22 in the cutting area 192b is 0, and the sum of the number of the inorganic film layers of the first inorganic layer 21 and the second inorganic layer 22 in the display area 191 is 6.

In the OLED display panel provided by the embodiment of the present disclosure, the sum of the number of the inorganic film layers of the first inorganic layer and the second inorganic layer in the cutting area is less than the sum of the number of the inorganic film layers of the first inorganic layer and the second inorganic layer in the display area, part of the inorganic layers in the cutting area may be removed, and the number of the inorganic layers located in the cutting area is fewer. Since micro-cracks are not easy to diffuse in the organic layers, the number of the film layers in which the micro-cracks may diffuse is reduced, and difficulties of crack diffusion are increased, so that when the OLED display panel generates the micro-cracks, the micro-cracks are not easy to diffuse into the display area, thereby avoiding the problem of encapsulation failure caused by the crack diffusion to the display area.

In one embodiment, the number of the inorganic film layers of the first inorganic layer is 0, and the number of the inorganic film layers of the second inorganic layer located in the cutting area is 0, which means that both the first inorganic layer and the second inorganic layer are not provided in the cutting area.

In one embodiment, the first inorganic layer includes a buffer layer, a first gate insulating layer, a second gate insulating layer, and an interlayer insulating layer, and the second inorganic layer includes touching insulating layers in the display area. In the cutting area, the OLED display panel includes at most three film layers of the buffer layer, the first gate insulating layer, the second gate insulating layer, the interlayer insulating layer, the first touching insulating layer, and the second touching insulating layer. By removing part of the inorganic layers in the cutting area, the number of the inorganic layers located in the cutting area is fewer, which reduces the number of the film layers in which the micro-cracks may diffuse, increases the difficulties of the crack diffusion, so that when the OLED display panel generates the micro-cracks, the micro-cracks are not easy to diffuse into the display area, thereby avoiding the problem of encapsulation failure caused by the crack diffusion to the display area.

In one embodiment, the first inorganic layer includes at most two layers of the buffer layer, the gate insulating layer, and the interlayer insulating layer, and/or the number of the inorganic film layers of the second inorganic layer located in the cutting area is 0, which reduces the number of the inorganic film layers in the cutting area, reduces the risk of the crack diffusion, and improves the encapsulation effect of the display panel.

In one embodiment, the first inorganic layer includes the buffer layer, the gate insulating layer, and the interlayer insulating layer in the cutting area, and the second inorganic layer is not provided in the cutting area. In another embodiment, the first inorganic layer includes the buffer layer and the gate insulating layer in the cutting area, and the interlayer insulating layer is not provided in the cutting area. However, the present disclosure is not limited to the embodiments mentioned above, and is limited only in the cutting area, where the sum of the number of the inorganic film layers of the first inorganic layer and the second inorganic layer in the cutting area is less than the sum of the number of the inorganic film layers of the first inorganic layer and the second inorganic layer in the display area. For example, the first inorganic layer includes the buffer layer and the interlayer insulating layer in the cutting area, the gate insulating layer is not provided in the cutting area, and the second inorganic layer includes the touching insulating layer.

In an embodiment, as shown in FIG. 1, in the display area, the first inorganic layer 21 includes the buffer layer 121, a first gate insulating layer 123, a second gate insulating layer 125, and the interlayer insulating layer 127, and the second inorganic layer 22 includes a first touching insulating layer 161 and a second touching insulating layer 163. In the cutting area 192b, the OLED display panel 1 includes at most five film layers of the buffer layer 121, the first gate insulating layer 123, the second gate insulating layer 125, the interlayer insulating layer 127, the first touching insulating layer 161, and the second touching insulating layer 163, so that at least one inorganic layer in the cutting area may be removed, the number of inorganic layers in the cutting area may be reduced, and the difficulties of micro-crack diffusion may be increased. As a result, when the OLED display panel generates the micro-cracks, the micro-cracks do not easily diffuse into the display area, thereby avoiding the problem of encapsulation failure caused by the crack diffusion to the display area.

In one embodiment, one film layer of the buffer layer 121, the first gate insulating layer 123, the second gate insulating layer 125, the interlayer insulating layer 127, the first touching insulating layer 161, and the second touching insulating layer 163 in the cutting area 192b may be removed. In another embodiment, two, three, four, five, or six film layers of the buffer layer 121, the first gate insulating layer 123, the second gate insulating layer 125, the interlayer insulating layer 127, the first touching insulating layer 161, and the second touching insulating layer 163 in the cutting area 192b may further be removed. For example, in the cutting area 192b, the first inorganic layer 21 includes the buffer layer 121, the first gate insulating layer 123, the second gate insulating layer 125, and the interlayer insulating layer 127, and the second inorganic layer 22 is not provided in the cutting area 192b.

In one embodiment, a material of the first touching insulating layer includes silicon oxide, silicon nitride, and silicon oxynitride.

In one embodiment, a thickness of the first touching insulating layer ranges from 100 Å to 10000 Å.

In one embodiment, a material of the second touching insulating layer includes silicon oxide, silicon nitride, and silicon oxynitride.

In one embodiment, a thickness of the second touching insulating layer ranges from 100 Å to 10000 Å.

In view of the problem that the number of the inorganic film layers in the cutting area is larger, the cracks easily diffuse into the display area, and water and oxygen invade from the cracks to the display area, resulting in the encapsulation failure of the OLED display panel. In one embodiment, as shown in FIG. 1, the encapsulation layer 15 includes a first inorganic encapsulation layer 151, a second inorganic encapsulation layer 153, and an organic encapsulation layer 152 disposed between the first inorganic encapsulation layer 151 and the second inorganic encapsulation layer 153.

The OLED display panel 1 further includes a flat layer 17 disposed on a side of the touching layer 16 away from the encapsulation layer 15. In the cutting area 192b, a side of the light-emitting functional layer 14 is in contact with at least part of the substrate 11, and the other side of the light-emitting functional layer 14 is in contact with at least part of the first inorganic encapsulation layer 151, the first inorganic encapsulation layer 151 is in contact with the second inorganic encapsulation layer 153, and the second inorganic encapsulation layer 151 is in contact with the flat layer 17. The side of the light-emitting functional layer 14 is in contact with the substrate 11, and the other side of the light-emitting functional layer 14 is in contact with the first inorganic encapsulation layer 151 in the cutting area 192b, so that the first inorganic layer 21 in the cutting area 192b may be removed, the first inorganic encapsulation layer 151 is in contact with the second inorganic encapsulation layer 153, and water and oxygen may be prevented from intruding into the display area from the organic layers. The second inorganic encapsulation layer 151 is in contact with the flat layer 17, so that the second inorganic layer 22 in the cutting area 192b may be removed. Therefore, in the OLED display panel, both the first inorganic layer and the second inorganic layer located in the cutting area are removed, so that when the OLED display panel generates the micro-cracks, the cracks do not easily diffuse into the display area. The light-emitting functional layer and the flat layer are disposed in the cutting area, so that the micro-cracks do not easily diffuse in the organic layers, which further reduces the risk of the cracks diffusing into the display area. At the same time, the first inorganic encapsulation layer and the second inorganic encapsulation layer are disposed in the cutting area, which improves the encapsulation effect of the OLED display panel, and prevents the water and oxygen from invading.

In one embodiment, as shown in FIG. 1, the light-emitting functional layer 14 includes a pixel electrode layer 141, a pixel defining layer 142, and a light-emitting device layer 143. The light-emitting device layer 143 is disposed in the cutting area 192b, and the light-emitting device layer 143 includes a hole transport layer, a light-emitting layer, an electron injection layer, and a common electrode layer. These film layers are made of organic materials or metals, have good ductility, and the cracks do not easily diffuse in these film layers, which may prevent the cracks from diffusing into the display area and further reduce the risk of the cracks diffusing into the display area.

In one embodiment, as shown in FIG. 1, since the light-emitting functional layer 14 is disposed in the cutting area 192b, in order to prevent water and oxygen from invading the light-emitting functional layer, the OLED display panel 1 further includes an encapsulation area 192a, and the light-emitting device layer 143 is disconnected in the undercut structure disposed in the encapsulation area 192a, thereby preventing water and oxygen from invading the light-emitting device layer 143 and improving the encapsulation performance of the OLED display panel.

In one embodiment, the second source-drain layer 131 is described in detail in FIG. 1 as an example of forming the undercut structure, but the embodiment of the present disclosure is not limited to this. For example, the undercut structure may be formed by an inorganic layer and a metal layer to disconnect the organic layer and prevent water and oxygen from invading, and a number of the undercut structures may be multiple.

In one embodiment, when the light-emitting functional layer is disposed in the cutting area, one film layer of the light-emitting functional layer may be disposed in the cutting area, for example, the electron transport layer may be disposed in the cutting area. Or, a plurality of film layers of the light-emitting functional layer may be disposed in the cutting area, for example, the film layers from the pixel electrode layer to the common electrode layer may be disposed in the cutting area.

In an embodiment, a material of the first inorganic encapsulation layer includes silicon oxide, silicon nitride, and silicon oxynitride.

In an embodiment, a thickness of the first inorganic encapsulation layer ranges from 500 Å to 30000 Å.

In an embodiment, a material of the second inorganic encapsulation layer includes silicon oxide, silicon nitride, and silicon oxynitride.

In an embodiment, a thickness of the second inorganic encapsulation layer ranges from 500 Å to 30000 Å.

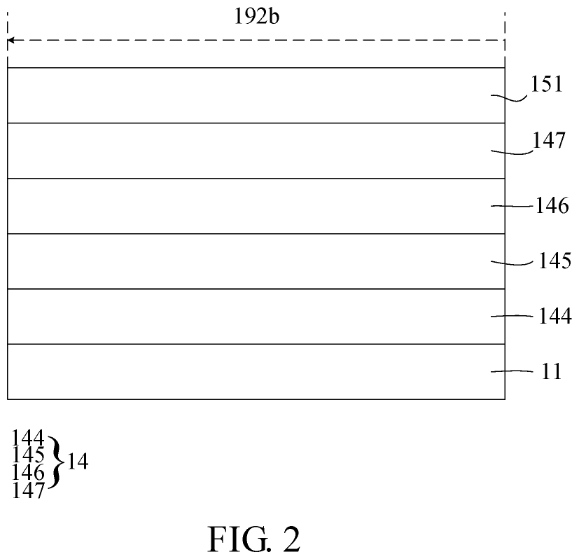

In one embodiment, as shown in FIG. 2, the light-emitting functional layer 14 includes the hole transport layer 144, the light-emitting layer 145, the electron transport layer 146, and the common electrode layer 147. The light-emitting layer 145 is disposed between the light-emitting layer 145 and the common electrode layer 147. The electron transport layer 146 is disposed between the light-emitting layer 145 and the common electrode layer 147. In the cutting area 192b, the hole transport layer 144 is in contact with the substrate 11, and the common electrode layer 147 is in contact with the first inorganic encapsulation layer 151. By removing the first inorganic layer in the cutting area, the number of the film layers in the cutting area is reduced, and the difficulties of the crack diffusion are increased. The hole transport layer is in contact with the substrate, and the common electrode layer is in contact with the first inorganic encapsulation layer, which reduces a cutting stress by using the ductility of the organic layer and the metal layer, thereby further increasing the difficulties of the crack diffusion, preventing water and oxygen from invading into the display area, and improving the encapsulation performance of the OLED display panel.

Specifically, the embodiments mentioned above have been described in detail by taking the hole transport layer, the light-emitting layer, the electron transport layer, and the common electrode layer as an example, but the embodiment of the present disclosure is not limited thereto. For example, part of the film layers of the hole transport layer, the light-emitting layer, the electron transport layer, and the common electrode layer may be provided in the cutting area, or the hole injection layer and the electron injection layer may be provided in the cutting area when the light-emitting functional layer includes the hole injection layer and the electron injection layer.

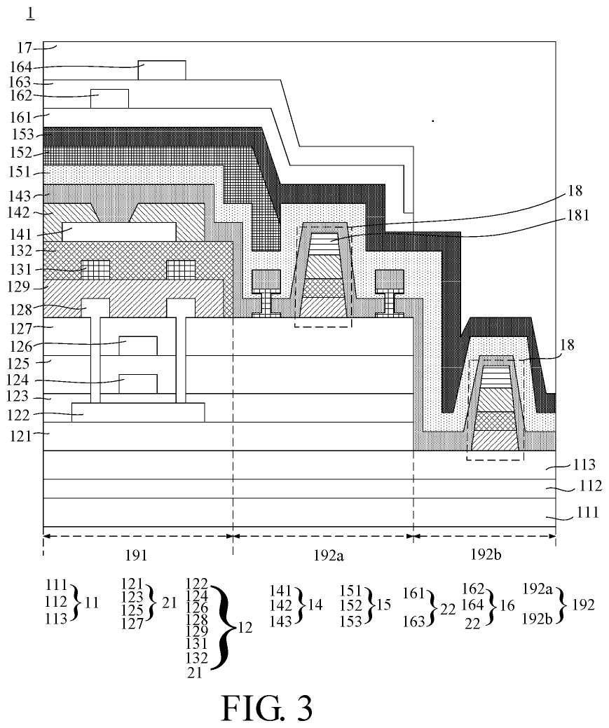

In view of the problem that the cracks may still diffuse into the display area when the inorganic layers in the cutting area are removed. In one embodiment, as shown in FIG. 3, the driving circuit layer 12 further includes a first planarization layer 129 and a second planarization layer 132 disposed between the first planarization layer 129 and the light emitting-functional layer 14.

The light-emitting functional layer 14 further includes the pixel defining layer 142 disposed between the second planarization layer 132 and the encapsulation layer 15.

The OLED display panel further includes a spacer column 181 and a retaining wall 18. The retaining wall 18 includes the first planarization layer 129, the second planarization layer 132, the pixel definition layer 142, and the spacer column 181 stacked in sequence. In the cutting area 192b, the retaining wall 18 is disposed between the substrate 11 and the light-emitting functional layer 14, so that the retaining wall 18 may block the cutting cracks of the OLED display panel to prevent the cracks from extending to the display area, thereby preventing water and oxygen from intruding into the display area, and improving the encapsulation effect of the display panel.

In one embodiment, the materials of the first planarization layer 129, the second planarization layer 132, the pixel definition layer 142, and the spacer column 181 include organic materials. The materials of each film layer of the retaining wall 18 is made of organic materials, so that when the retaining wall 18 is provided in the cutting area, the retaining wall 18 may block the cracks to prevent the cracks from extending to the display area, thereby preventing water and oxygen from invading into the display area, and improving the encapsulation effect of the display panel.

In one embodiment, since the retaining wall is disposed in the encapsulation area of the OLED display panel, the retaining wall is disposed in the cutting area in the present disclosure, so there is no need to increase the processes of manufacturing the OLED display panel and a thickness of the OLED display panel, thereby improving the manufacturing efficiency of the OLED display panel and avoiding increasing the thickness of the OLED display panel.

Specifically, the embodiments mentioned above are described in detail by taking the retaining wall including the first planarization layer, the second planarization layer, the pixel definition layer, and the spacer column as an example, but the embodiment of the present disclosure is not limited thereto. For example, the retaining wall may only include two or three film layers of the first planarization layer, the second planarization layer, the pixel definition layer, and the spacer column. When other designs are used for the film layers of the OLED display panel, the retaining wall may also be designed with other film layers accordingly. For example, the retaining wall includes the planarization layers and the spacer column.

Specifically, only one retaining wall is disposed in the cutting area shown in FIG. 3, but the embodiment of the present disclosure is not limited thereto. For example, a plurality of retaining walls are disposed in the cutting area.

In one embodiment, a thickness of the first planarization layer ranges from 5000 Å to 30000 Å.

In one embodiment, a thickness of the second planarization layer ranges from 5000 Å to 30000 Å.

In one embodiment, a thickness of the pixel definition layer ranges from 5000 Å to 30000 Å.

In one embodiment, a thickness of the spacer column ranges from 5000 Å to 30000 Å.

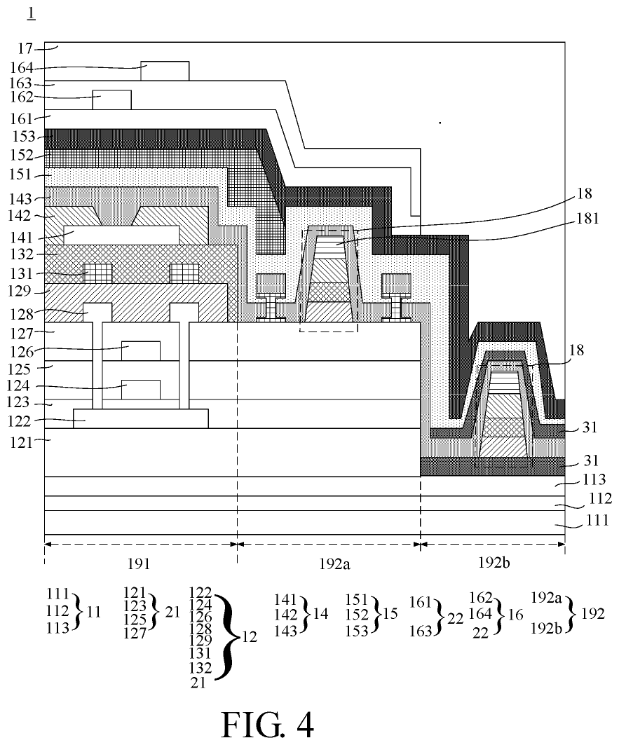

In view of the problem that the cracks may still diffuse into the display area when the inorganic layers in the cutting area are removed. In one embodiment, as shown in FIG. 4, the OLED display panel 1 further includes a metal pattern 31 disposed at least one side of the light-emitting functional layer 14 in the cutting area 192b, which may reduce a stress generated when cutting the OLED display panel and a stress generated when using the OLED display panel, thereby reducing the risk that the cracks generated by cutting extend to the display area, preventing the water and oxygen from invading into the display area, and improving the encapsulation effect of the display panel.

In one embodiment, as shown in FIG. 4, the metal pattern 31 may only be disposed in the cutting area 192b. Since the number of the film layers in the cutting area 192b is less than the number of the film layers in the display area 191, the metal pattern 31 added in the cutting area 192b may not increase the thickness of the OLED display panel. Since the ductility of the metal pattern is better, no matter the stress caused by cutting or bending, it may be released through the metal pattern, which prevents the cracks from extending to the display area due to excessive cutting stress of the OLED display panel, and further prevents the OLED display panel from being damaged by the excessive stress when the OLED display panel is bent.

In one embodiment, a material of the metal pattern includes one of molybdenum, titanium/aluminum/titanium laminate, and indium tin oxide/silver/indium tin oxide.

In one embodiment, a thickness of the metal pattern ranges from 1000 Å to 20000 Å.

In view of the problem that the process steps of OLED display panel are increased when adding the metal pattern, resulting in a lower manufacturing efficiency of OLED display panel. In one embodiment, as shown in FIG. 4, the driving circuit layer 12 further includes a first metal layer 124, a second metal layer 126, a first source-drain layer 128, and a second source-drain layer 131. In the cutting area 192b, the metal pattern 31 is disposed between the light-emitting functional layer 14 and the substrate 11, and one of the first metal layer 124, the second metal layer 126, the first source-drain layer 128, and the second source-drain layer 131 includes the metal pattern 31. By forming the metal pattern in one of the first metal layer, the second metal layer, the first source-drain layer, and the second source-drain layer, the manufacturing efficiency of the OLED display panel is improved without additional process steps.

In one embodiment, the metal pattern may be formed only in the first metal layer, only in the second metal layer, only in the first source-drain layer, or only in the second source-drain layer.

In one embodiment, when the metal pattern is formed in the first metal layer, the second metal layer, the first source-drain layer, and the second source-drain layer, a plurality of layers of the first metal layer, the second metal layer, the first source-drain layer, and the second source-drain layer may be superimposed to form a metal pattern.

In one embodiment, as shown in FIG. 4, the metal pattern 31 is disposed between the light-emitting functional layer 14 and the first inorganic encapsulating layer 15 in the cutting area 192b. The OLED display panel further includes a metal layer, and the metal layer includes the metal pattern 31. By adding the metal layer in the OLED display panel, and the metal pattern is formed in the metal layer, the influence of a manufacturing process of the metal pattern on the manufacturing processes of other film layers of the OLED display panel is avoided. Further, the metal pattern may reduce the stress generated during cutting the OLED display panel and the stress generated when the OLED display panel is used, which reduces the risk of the cracks generated by cutting extending to the display area, and prevents the water and oxygen from invading into the display area, and improves the encapsulation effect of the display panel.

In one embodiment, the light-emitting functional layer further includes a common electrode layer. The non-display area includes an encapsulation area located between the display area and the cutting area. The metal pattern is in contact with the common electrode layer at a junction of the display area and the encapsulation area, which avoids increasing the thickness of the OLED display panel. Further, the metal pattern may reduce an impedance of the common electrode layer, so that the power consumption of the OLED display panel is reduced. At the same time, the metal pattern located in the cutting area may reduce the stress generated when the OLED display panel is cut and the stress generated when the OLED display panel is used, which reduces the risk of the cracks generated by cutting extending to the display area, and prevents the water and oxygen from invading into the display area, and improves the encapsulation effect of the display panel.

Specifically, the embodiments mentioned above have been described in detail with the metal patterns respectively disposed between the substrate and the light-emitting functional layer, and the metal pattern disposed between the light-emitting functional layer and the first inorganic encapsulation layer as examples, but the embodiments of the present disclosure are not limited thereto, for example, the metal pattern may be disposed on both sides of the light-emitting functional layer.

Specifically, the embodiments mentioned above have been described in detail with in the display area of the OLED display panel, where the first inorganic layer includes the buffer layer, the gate insulating layer, and the interlayer insulating layer, the second inorganic layer includes the touching insulating layer, the first inorganic layer includes the buffer layer, the first gate insulating layer, a second gate insulating layer, and the interlayer insulating layer, and the second inorganic layer includes the first touching insulating layer and the second touching insulating layer, but the embodiment of the present disclosure is not limited thereto. For example, the first inorganic layer may include the inorganic films such as a barrier layer, a first interlayer insulating layer, and a second interlayer insulating layer. Similarly, part or all of the films of the first inorganic layer and/or the second inorganic layer located in the cutting area may be removed to reduce the number of the inorganic layers in the cutting area and increase the difficulties of micro-crack diffusion, so that when the micro-cracks generate in the OLED display panel, the cracks do not easily diffuse into the display area, thereby avoiding the problem of encapsulation failure caused by crack diffusion to the display area.

In one embodiment, as shown in FIG. 1, the substrate 11 includes a first flexible layer 111, the barrier layer 112, and a second flexible layer 113.

In one embodiment, as shown in FIG. 1, the driving circuit layer 12 further includes an active layer 122.

In one embodiment, as shown in FIG. 1, the touching layer 16 includes a first electrode layer 162 and a second electrode layer 164.

In one embodiment, the cutting area surrounds the display area.

Meanwhile, the embodiment of the present disclosure provides an OLED display device including the OLED display panel as described in any of the above embodiments and an electronic element.

As can be seen from the above embodiments:

Beneficial effects are as follows: The OLED display panel and the OLED display device are provided by the present disclosure. The OLED display panel includes the substrate, the driving circuit layer, the light-emitting functional layer, the encapsulation layer, and the touching layer. The driving circuit layer is disposed on the side of the substrate and includes the first inorganic layer having the plurality of inorganic film layers. The light-emitting functional layer is disposed on the side of the driving circuit layer away from the substrate. The encapsulation layer is disposed on the side of the light-emitting functional layer away from the driving circuit layer. The touching layer is disposed on the side of the encapsulation layer away from the light-emitting functional layer and includes a second inorganic layer having one or more inorganic film layers. The OLED display panel further includes the display area and the non-display area, and the non-display area includes the cutting area disposed at the side of the display area. The sum of the number of the inorganic film layers of the first inorganic layer and the second inorganic layer in the cutting area is less than the sum of a number of the inorganic film layers of the first inorganic layer and the second inorganic layer in the display area, so that part of the inorganic layers in the cutting area may be removed, and the number of the inorganic layers located in the cutting area is fewer. Since micro-cracks are not easy to diffuse in the organic layers, the number of the film layers in which the micro-cracks may diffuse is reduced, and difficulties of crack diffusion are increased, so that when the OLED display panel generates the micro-cracks, the micro-cracks are not easy to diffuse into the display area, thereby avoiding the problem of encapsulation failure caused by the crack diffusion to the display area.

In the foregoing embodiments, the description of each of the embodiments has respective focuses. For a part that is not described in detail in an embodiment, reference may be made to relevant descriptions in other embodiments. Details are not further described herein.

The present disclosure has been described in detail with respect to an OLED display panel and an OLED display device according to an embodiment of the present disclosure. The principles and implementations of the present disclosure are described in detail here with specific examples. The above description of the embodiments is merely intended to help understand the method and core ideas of the present disclosure. At the same time, a person skilled in the art may make changes in the specific embodiments and disclosure scope according to the idea of the present disclosure. In conclusion, the content of the present specification should not be construed as a limitation to the present disclosure.

What is claimed is:

1. An organic light-emitting diode (OLED) display panel, comprising:
a substrate;
a driving circuit layer, disposed on the substrate and comprising a first inorganic layer having a plurality of inorganic film layers;
a light-emitting functional layer, disposed on a side of the driving circuit layer away from the substrate;
an encapsulation layer, disposed on a side of the light-emitting functional layer away from the driving circuit layer; and
a touching layer, disposed on a side of the encapsulation layer away from the light-emitting functional layer and comprising a second inorganic layer having one or more inorganic film layers;
wherein the OLED display panel comprises a display area and a non-display area, the non-display area comprises a cutting area disposed at a side of the display area; a sum of a number of the inorganic film layers of the first inorganic layer and the second inorganic layer in the cutting area is less than a sum of a number of the inorganic film layers of the first inorganic layer and the second inorganic layer in the display area.

2. The OLED display panel according to claim 1, wherein in the display area, the first inorganic layer comprises a buffer layer, a first gate insulating layer, a second gate insulating layer, and an interlayer insulating layer; the second inorganic layer comprises a first touching insulating layer and a second touching insulating layer; in the cutting area, the OLED display panel comprises five or fewer film layers among the buffer layer, the first gate insulating layer, the second gate insulating layer, the interlayer insulating layer, the first touching insulating layer, and the second touching insulating layer.

3. The OLED display panel according to claim 2, wherein the encapsulation layer comprises a first inorganic encapsulation layer, a second inorganic encapsulation layer, and an organic encapsulation layer disposed between the first inorganic encapsulation layer and the second inorganic encapsulation layer;
the OLED display panel further comprises a flat layer disposed on a side of the touching layer away from the encapsulation layer; in the cutting area, a side of the light-emitting functional layer is in contact with the substrate, and the other side of the light-emitting functional layer is in contact with the first inorganic encapsulation layer, the first inorganic encapsulation layer is in contact with the second inorganic encapsulation layer, and the second inorganic encapsulation layer is in contact with the flat layer.

4. The OLED display panel according to claim 3, wherein the light-emitting functional layer comprises a hole transport layer, a light-emitting layer, an electron transport layer, and a common electrode layer, the light-emitting layer is disposed between the hole transport layer and the electron transport layer, and the electron transport layer is disposed between the light-emitting layer and the common electrode layer; in the cutting area, the hole transport layer is in contact with the substrate, and the common electrode layer is in contact with the first inorganic encapsulation layer.

5. The OLED display panel according to claim 3, wherein the driving circuit layer further comprises a first planarization layer and a second planarization layer disposed between the first planarization layer and the light-emitting functional layer;
the light-emitting functional layer further comprises a pixel defining layer disposed between the second planarization layer and the encapsulation layer; and
the OLED display panel further comprises a spacer column and a retaining wall disposed between the substrate and the light-emitting functional layer in the cutting area, and the retaining wall comprises the first planarization layer, the second planarization layer, the pixel definition layer, and the spacer column stacked in sequence.

6. The OLED display panel according to claim 3, further comprising:
a metal pattern, disposed at one or more sides of the light-emitting functional layer in the cutting area.

7. The OLED display panel according to claim 6, wherein the driving circuit layer further comprises a first metal layer, a second metal layer, a first source-drain layer, and a second source-drain layer; in the cutting area, the metal pattern is disposed between the light-emitting functional layer and the substrate, and one of the first metal layer, the second metal layer, the first source-drain layer, and the second source-drain layer comprises the metal pattern.

8. The OLED display panel according to claim 6, wherein the metal pattern is disposed between the light-emitting functional layer and the first inorganic encapsulating layer in the cutting area; the OLED display panel further comprises a metal layer, and the metal pattern is disposed in the metal layer.

9. The OLED display panel according to claim 8, wherein the light-emitting functional layer further comprises a common electrode layer; the non-display area comprises an encapsulation area located between the display area and the cutting area, and the metal pattern is in contact with the common electrode layer at a junction of the display area and the encapsulation area.

10. The OLED display panel according to claim 9, wherein the light-emitting functional layer further comprises a light-emitting device layer disconnected at an undercut structure provided in the encapsulation area.

11. An organic light-emitting diode (OLED) display device, comprising an OLED display panel and an electronic element, wherein the OLED display panel comprises:
a substrate;
a driving circuit layer, disposed on a side of the substrate and comprising a first inorganic layer having a plurality of inorganic film layers;
a light-emitting functional layer, disposed on a side of the driving circuit layer away from the substrate;
an encapsulation layer, disposed on a side of the light-emitting functional layer away from the driving circuit layer; and
a touching layer, disposed on a side of the encapsulation layer away from the light-emitting functional layer and comprising a second inorganic layer having one or more inorganic film layers;
wherein the OLED display panel comprises a display area and a non-display area, the non-display area comprises a cutting area disposed at a side of the display area; a sum of a number of the inorganic film layers of the first inorganic layer and the second inorganic layer in the cutting area is less than a sum of a number of the inorganic film layers of the first inorganic layer and the second inorganic layer in the display area.

12. The OLED display device according to claim 11, wherein in the display area, the first inorganic layer comprises a buffer layer, a first gate insulating layer, a second gate insulating layer, and an interlayer insulating layer; the second inorganic layer comprises a first touching insulating layer and a second touching insulating layer; in the cutting area, the OLED display panel comprises five or fewer film layers among the buffer layer, the first gate insulating layer, the second gate insulating layer, the interlayer insulating layer, the first touching insulating layer, and the second touching insulating layer.

13. The OLED display device according to claim 12, wherein the encapsulation layer comprises a first inorganic encapsulation layer, a second inorganic encapsulation layer, and an organic encapsulation layer disposed between the first inorganic encapsulation layer and the second inorganic encapsulation layer;
the OLED display panel further comprises a flat layer disposed on a side of the touching layer away from the encapsulation layer; in the cutting area, a side of the light-emitting functional layer is in contact with the substrate, and the other side of the light-emitting functional layer is in contact with the first inorganic encapsulation layer, the first inorganic encapsulation layer is in contact with the second inorganic encapsulation layer, and the second inorganic encapsulation layer is in contact with the flat layer.

14. The OLED display device according to claim 13, wherein the light-emitting functional layer comprises a hole transport layer, a light-emitting layer, an electron transport layer, and a common electrode layer, the light-emitting layer is disposed between the hole transport layer and the electron transport layer, and the electron transport layer is disposed between the light-emitting layer and the common electrode layer; in the cutting area, the hole transport layer is in contact with the substrate, and the common electrode layer is in contact with the first inorganic encapsulation layer.

15. The OLED display device according to claim 13, wherein the driving circuit layer further comprises a first planarization layer and a second planarization layer disposed between the first planarization layer and the light-emitting functional layer;
the light-emitting functional layer further comprises a pixel defining layer disposed between the second planarization layer and the encapsulation layer; and
the OLED display panel further comprises a spacer column and a retaining wall disposed between the substrate and the light-emitting functional layer in the cutting area, and the retaining wall comprises the first planarization layer, the second planarization layer, the pixel definition layer, and the spacer column stacked in sequence.

16. The OLED display device according to claim 13, wherein the OLED display panel further comprises a metal pattern disposed at one or more sides of the light-emitting functional layer in the cutting area.

17. The OLED display device according to claim 16, wherein the driving circuit layer further comprises a first metal layer, a second metal layer, a first source-drain layer, and a second source-drain layer; the metal pattern is disposed between the light-emitting functional layer and the substrate, and one of the first metal layer, the second metal layer, the first source-drain layer, and the second source-drain layer comprises the metal pattern.

18. The OLED display device according to claim 16, wherein the metal pattern is disposed between the light-emitting functional layer and the first inorganic encapsulating layer in the cutting area; the OLED display panel further comprises a metal layer, and the metal pattern is disposed in the metal layer.

19. The OLED display device according to claim 18, wherein the light-emitting functional layer further comprises a common electrode layer; the non-display area comprises an encapsulation area located between the display area and the cutting area, and the metal pattern is in contact with the common electrode layer at a junction of the display area and the encapsulation area.

20. The OLED display device according to claim 19, wherein the light-emitting functional layer further comprises a light-emitting device layer disconnected at an undercut structure in the encapsulation area.
